(19) United States
(12) Patent Application Publication
(10) Pub. No.: US 2023/0016552 A1
(43) Pub. Date: Jan. 19, 2023

(54) SEMICONDUCTOR DEVICE

(71) Applicant: RENESAS ELECTRONICS CORPORATION, Tokyo (JP)

(72) Inventors: Tohru KAWAI, Tokyo (JP); Yasutaka NAKASHIBA, Tokyo (JP)

(21) Appl. No.: 17/946,368

(22) Filed: Sep. 16, 2022

Related U.S. Application Data
(63) Continuation of application No. 16/928,872, filed on Jul. 14, 2020.

(51) Int. Cl. H01L 23/485; H01L 29/872

(52) U.S. Cl. CPC H01L 23/485; H01L 29/872

(57) ABSTRACT

A semiconductor device includes a semiconductor substrate, a buried insulating film, a first conductive film, an insulating layer, a first contact and a second contact. The semiconductor substrate includes a first semiconductor region having a first conductive type and a second semiconductor region having a second conductive type. The buried insulating film surrounds the second semiconductor region in plan view. The first conductive film directly contacts with the first and second semiconductor regions. The first and second contacts overlap with the second semiconductor region in plan view and reach the first conductive film. The first contact is adjacent to the second contact along a first side of the second semiconductor region in plan view. In a direction along the first side, a first distance between the second semiconductor region and the buried insulating film is greater than a second distance between the first contact and the second contact.

### CROSS-REFERENCE TO RELATED APPLICATIONS

This is a Continuation of U.S. patent application Ser. No. 16/928,872 filed on Jul. 14, 2020, including the specification, drawings and abstract are incorporated herein by reference in its entirety.

### BACKGROUND

The present disclosure relates to a semiconductor device and, for example, to a semiconductor device including a Schottky barrier diode.

There is a disclosed technique listed below.
[Patent Document 1] Japanese Unexamined Patent Application Publication No. 2013-008997

A semiconductor device including a Schottky barrier diode is known (see, for example, Patent Document 1). The Schottky barrier diode has low-voltage and high-speed switching characteristics. According to the Schottky barrier diagram, the unintended reverse current is restrained.

A semiconductor device described in Patent Document 1 includes an n-type cathode region formed on a main surface of a semiconductor substrate, an anode conductive film formed on the n-type cathode region, an interlayer insulating film formed on the semiconductor substrate such that the interlayer insulating film covers the anode conductive film, and a contact plug formed in the interlayer insulating film such that the contact plug reaches the anode conductive film. The n-type cathode region and the anode conductive film form a Schottky junction with each other. That is, in the semiconductor device described in Patent Document 1, the Schottky barrier diode is formed of the n-type cathode region and the anode conductive film.

### SUMMARY

In a semiconductor device described in Patent Document 1, when a through hole for the contact plug is formed in the interlayer insulating film, the through hole may penetrate the anode conductive film. Therefore, the contact plug reaches the n-type cathode region. As a result, the Schottky barrier diode does not function. Thus, there is a room for improving the conventional semiconductor device from the viewpoint of improving reliability.

It is a problem of the embodiment to improve the reliability of the semiconductor device. Other problems and novel features will become apparent from the description of the specification and drawings.

A semiconductor device according to embodiments includes a semiconductor substrate including a first semiconductor region having a first conductive type, and a second semiconductor region having a second conductive type opposite to the first conductive type, a buried insulating film formed on a main surface of the semiconductor substrate such that the buried insulating film surrounds the second semiconductor region in plan view, a first conductive film formed on the semiconductor substrate such that the first conductive film directly contacts with the first semiconductor region and the second semiconductor region, an insulating layer formed on the semiconductor substrate such that the insulating layer covers the first conductive film, a first contact formed in the insulating film such that the first contact overlaps with the second semiconductor region in plan view, and reaches the first conductive film, and a second contact formed in the insulating film such that the second contact overlaps with the second semiconductor region in plan view, and reaches the first conductive film, The second semiconductor region has a first side and a second side opposite to the first side. The first contact is adjacent to the second contact along the first side of the second semiconductor region in plan view. In a direction along the first side, a first distance between the second semiconductor region and the insulating layer is greater than a second distance between the first contact and the second contact.

In the semiconductor device according to the embodiments, it is possible to improve the reliability of the semiconductor device.

### BRIEF DESCRIPTION OF THE DRAWINGS

FIG. 1 is a plan view showing an exemplary configuration of a main portion of a semiconductor device according to an embodiment.

FIG. 2 is a cross-sectional view showing an exemplary configuration of the main portion of the semiconductor device according to the embodiment.

FIG. 3 is a cross-sectional view showing an exemplary step included in a method of manufacturing the semiconductor device according to the embodiment.

FIG. 4 is a cross-sectional view showing an exemplary step included in the method of manufacturing the semiconductor device according to the embodiment.

FIG. 5 is a cross-sectional view showing an exemplary step included in the method of manufacturing the semiconductor device according to the embodiment.

FIG. 6 is a cross-sectional view showing an exemplary step included in the method of manufacturing the semiconductor device according to the embodiment.

FIG. 7 is a cross-sectional view showing an exemplary step included in the method of manufacturing the semiconductor device according to the embodiment.

FIG. 8 is a cross-sectional view showing an exemplary step included in the method of manufacturing the semiconductor device according to the embodiment.

FIG. 9 is a cross-sectional view showing an exemplary configuration of a main portion of a semiconductor device according to examined example.

FIG. 10 is a plan view showing an exemplary configuration of a main portion of a semiconductor device according to a comparative example.

FIG. 11 is a plan view showing an exemplary configuration of a main portion of a semiconductor device according to first modification of the embodiment.

FIG. 12 is a cross-sectional view showing an exemplary configuration of the main portion of the semiconductor device according to first modification of the embodiment.

FIG. 13 is a plan view showing an exemplary configuration of a main portion of a semiconductor device according to a second modification of the embodiment.

FIG. 14 is a cross-sectional view showing an exemplary configuration of the main portion of the semiconductor device according to second modification of the embodiment.

FIG. 15 is a plan view showing an exemplary configuration of a main portion of a semiconductor device according to a third modification of the embodiment.

FIG. 16 is a cross-sectional view showing an exemplary configuration of the main portion of the semiconductor device according to the third modification of the embodiment.

### DETAILED DESCRIPTION

Hereinafter, a semiconductor device according to an embodiment is described in detail by referring to the drawings. In the specification and drawings, the same or corresponding constituent elements are denoted by the same reference numerals or hatching, and overlapping descriptions are omitted. In the drawings, for convenience of description, the configuration may be omitted or simplified. In addition, a cross-sectional view may be shown as an end view from the viewpoint of visibility.

[Configuration of Semiconductor Device]

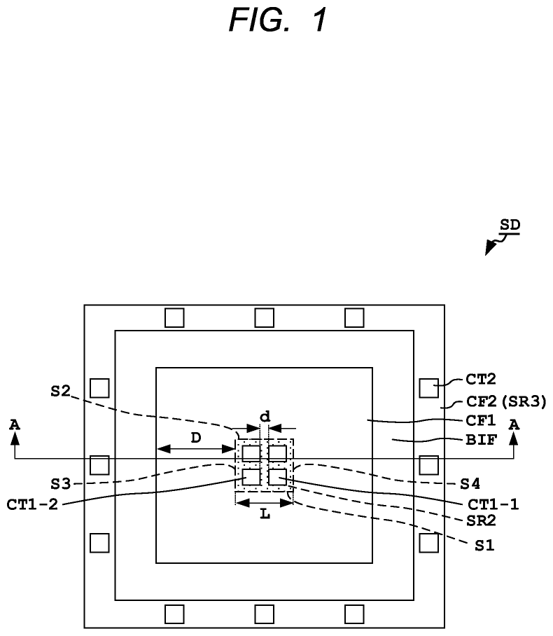

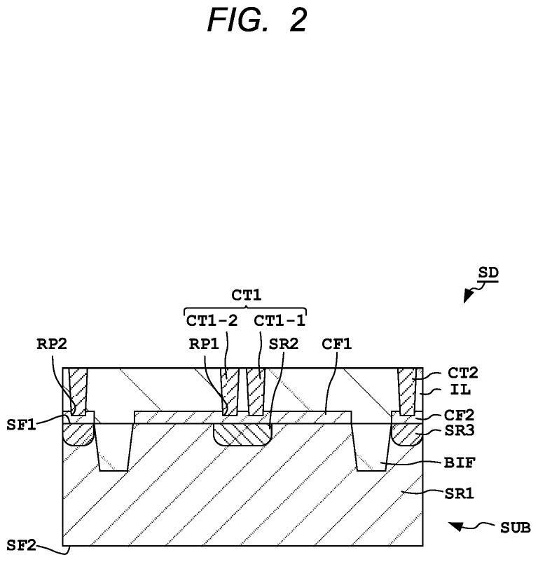

FIG. 1 is a plan view showing an exemplary configuration of a main portion of a semiconductor device SD according to present embodiment. FIG. 2 is a cross-sectional view showing an exemplary configuration of the main portion of the semiconductor device SD according to the present embodiment. FIG. 2 is a cross-sectional view taken along line A-A of FIG. 1.

The semiconductor device SD includes a semiconductor substrate SUB, a buried insulating film BIF, a first conductive film CF1, a second conductive film CF2, an insulating layer IL, a plurality of first contacts CT1, and a plurality of second contacts CT2. The respective configurations of the plurality of first contacts CT1 are the similar to each other except for the position. In the present embodiment, in particular, only a first contact CT1-1 and a first contact CT1-2 is described. The respective configurations of the plurality of second contacts CT2 are similar to each other except for the position. In the present embodiment, in particular, only one second contact CT2 is described.

The semiconductor substrate SUs has a first surface (main surface) SF1, and a second surface SF2 located on an opposite side of the first surface SF1. In the first surface SF1 of the semiconductor substrate SUB, a Schottky barrier diode is formed. The first surface SF1 of the semiconductor substrate SUB, a transistor, a semiconductor element such as a resistor and a capacitor may be formed. The type of the semiconductor substrate SUB is, for example, silicon single-crystal substrate.

The semiconductor substrate SUB includes a first semiconductor region SR1, a second semiconductor region SR2 and a third semiconductor region SR3.

The first semiconductor region SR1 has a first conductivity type. A surface of the first semiconductor region SR1 is located in the first surface SF1 of the semiconductor substrate SUB. A back surface of the first semiconductor region SR1 is located in the second surface SF2 of the semiconductor substrate SUB. The first conductive type is p-type or n-type. When the first conductive type is p-type, the first semiconductor region SL1 contains p-type impurities such as boron (B) and phosphorus (P). When the first conductive type is n-type, the first semiconductor region SR1 contains n-type impurities such as arsenic (As) and phosphorus (P). An impurity concentration of the first semiconductor region SR1, for example, 1×10¹⁴ cm⁻³ or more and 1×10¹⁶ cm⁻³ or less.

The second semiconductor region SR2 has a second conductive type opposite to the first conductivity type. A surface of the second semiconductor region SR2 is located in the first surface SF1 of the semiconductor substrate SUB. The second semiconductor region SR2 is adjacent to the first semiconductor region SR1. The impurity concentration of the second semiconductor region SR2, for example, 1×10¹⁹ cm⁻³ or more and 1×10²² cm⁻³ or less. In some cases, the first contact CT1 penetrates the first conductive film CF1. Even in this case, from the viewpoint of preventing conduction between the first contact CT1 and the first semiconductor region SR1, it is preferable that the impurity concentration of the second semiconductor region SR2 is greater. For example, it is preferable that the impurity concentration of the second semiconductor region SR2 is greater than the impurity concentration of the first semiconductor region SR1

The shape of the second semiconductor region SR2 in plan view is not particularly limited. A planar shape of the second semiconductor region SR2 is, for example, a substantially circular shape or substantially polygonal shape. In the present embodiment, the planar shape of the second semiconductor region SR2 is substantially rectangular. The second semiconductor region SR2 has a first side S1, a second side S2, a third side S3, and a fourth side S4. The first side S1, in plan view, is opposite to the second side S2. The third side S3, in plan view, is opposite to the fourth side S4.

A size of the second semiconductor region SR2 is preferably small in plan view. A Schottky junction of the Schottky barrier diode is formed of the first semiconductor region SR1 and the first conductive film CF1. The second semiconductor region SR2 does not constitute the Schottky barrier diode. That is, from the viewpoint of increasing the region which operates as the Schottky barrier diode, it is preferable that the size of the second semiconductor region SR2, in planar view, is small. In other words, in plan view, it is preferable that the second semiconductor region SR2 overlapping with the first conductive film CF1 is small. In the present embodiment, as shown in FIG. 1, in a direction along the first side S1, a distance D between the second semiconductor region SR2 and the buried insulating film BIF is greater than a distance d between the first contact CT1-1 and the first contact CT1-2.

The distance D is preferably, for example, 1 μm or more and 5 μm or less. The distance d is preferably, for example, 0.1 μm or more and 0.5 μm or less. The ratio D/d of the distance D to the distance d is preferably 2 or more and 50 or less.

Further, from the above viewpoint, in a direction along the first side S1, the distance D between the second semiconductor region SR2 and the buried insulating film BIF is greater than a length L of the second semiconductor region SR2 (a distance between the third side S3 and the fourth side S4) it is more preferable. The length L is preferably, for example, 0.5 μm or more and 2.0 μm or less. The ratio (D/L) of the distance D to the length L is preferably 0.5 or more and 10 or less.

The second semiconductor region SR2 may be separated from the buried insulating film BIF or may be adjacent to the buried insulating film BIF in plan view (third modification described later). In the present embodiment, the second semiconductor region SR2 is spaced apart from the buried insulating film BIF in plan view.

he third semiconductor region SR3 has the first conductive type. A surface of the third semiconductor region SR3 is located in the first surface SF1 of the semiconductor substrate SUB. The third semiconductor region SR3 is formed outside a region surrounded by the buried insulating film BIF in plan view. An impurity concentration of the third semiconductor region SR3, for example, 1×10¹⁹ cm⁻³ or more and 1×10²² cm⁻³ or less. From the viewpoint of reducing the contact resistance of the contact, it is preferable that the impurity concentration of the third semiconductor region SR3 is large. The impurity concentration of the third semiconductor region SR3 is preferably greater than the impurity concentration of the first semiconductor region SR1.

The buried insulating film BIF is formed on the first surface SF1 of the semiconductor substrate SUB. The buried insulating film BIF surrounds the second semiconductor region SR2 and the first conductive film CF1 in plan view. The buried insulating film BIF, in plan view, surrounds a region functioning as the Schottky barrier diode. The buried insulating film BIF is formed between the first conductive film CF1 and the second conductive film CF2 in plan view. The buried insulating film BIF is formed between the first contact CT1 (CT1-1, CT1-2) and the second contact CT2 in plan view. Material of the buried insulating film BIF is, for example, a silicone 2 (SiO₂).

The first conductive film CF1 is formed on the semiconductor substrate SUB such that the first conductive film CF1 directly contacts with the first semiconductor region SR1 and the second semiconductor region SR2. In the present embodiment, the first conductive film CF1 is directly contacts with a portion of an upper surface of the first semiconductor region SR1 and an entire of the upper surface of the second semiconductor region SR2. Thus, the first conductive film CF1 forms the first semiconductor region SR1 and the Schottky barrier diode (Schottky junction). In this case, since the first conductive type of the first semiconductor region SR1 differs from the second conductive type of the second semiconductor region SR2, a junction portion of the first conductive film CF1 and the second semiconductor region SR2 does not operate as a Schottky barrier diode.

The first conductive film CF1 includes a silicide layer having conductivity. The materials of the first conductive film CF1 are, for example, silicon and metals. The silicide layer contains a silicon and a compound of the metal. The silicide layer is, for example, a cobalt silicide layer or a nickel silicide layer. A thickness of the first conductive film CF1, for example, 10 nm or more and 40 nm or less.

It is preferable that a first recess portion RP1 is formed on the upper surface of the first conductive film CF1. Thus, when forming a through hole for the first contact CT1-1, CT1-2 in insulating layer IL, it is possible to reliably remove insulating layer IL. Therefore, since the first conductive film can be suppressed from remaining between the upper surface of the first conductive film CF1 and the first contact CT1-1, CT1-2, a contact resistance of the first conductive film CF1 and the first contact CT1 is reduced.

The first conductive film CF1 directly contacts with a lower surface of the first contact CT1-1, CT1-2 in the first recess portion RP1. The first conductive film CF1 may or may not directly contact with a side surface of the first contact CT1-1, CT1-2. The first conductive film CF1 preferably directly contacts with the side surface of the first contact CT1-1, CT1-2. Thus, since a contact area of the first conductive film CF1 and the first contact CT1 is increased, the contact resistance of the first conductive film CF1 and the first contact CT1 is reduced.

A depth of the first recess portion RP1 is not particularly limited. From the viewpoint of reducing the contact resistance of the first conductive film CF1 and the first contact CT1 by increasing the contact area of the first conductive film CF1 and the first contact CT1, it is preferable that the depth of the first recess portion RP1 is large.

The second conductive film CF2 is formed on the semiconductor substrate SUB such that the second conductive film CF2 directly contacts with the third semiconductor region SR3. When the semiconductor substrate SUB does not include the third semiconductor region SR3, the second conductive film CF2 directly contacts with the first semiconductor region SR1. Examples of materials and a thickness of the second conductive film CF2 are similar to the first conductive film CF1. A second recess portion RP2 is preferably formed on an upper surface of the second conductive film CF2. The operation of the second recess portion RP2 is the same as that of the first recess portion RP1.

The insulating layer IL is formed on the semiconductor substrate SUB such that the insulating layer IL covers the first conductive film CF1 and the second conductive film CF2. Materials for the insulating layer IL is, for example, silicon oxide. A thickness of the insulating layer IL is, for example, 0.5 μm or more and 2.0 μm or less.

The first contact CT1-1, CT1-2 is formed in the insulating layer IL such that the first contact CT1-1, CT1-2 overlaps with the second semiconductor region SR2 in plan view, and reaches the first conductive film CF1. The first contact CT1-1, CT1-2 is located inside a region surrounded by the buried insulating film BIF in plan view. The first contact CT1-1, CT1-2 directly contacts with the first conductive film CF1 within the first recess portion RP1 of the first conductive film CF1. The first contact CT1-1, in plan view, is adjacent to the first contact CT1-2 along the first side S1 and the second side S2 of the second semiconductor region SR2. That is, there is no any other contact between the first contact CT1-1 and the first contact CT1-2. The first side S1 and the third side S3 of the second semiconductor region SR2 extend along an alignment direction of the first contact CT1-1 and the first contact CT1-2.

As a configuration of the first contact CT1-1, CT1-2, a known configuration adopted as a contact plug (also simply referred to as “contact”) in the semiconductor technology can be adopted. The first contact CT1-1, CT1-2 includes, for example, a barrier film and a conductive film formed on the barrier film. Examples of materials for the barrier film include titanium (Ti), titanium nitride (TiN), tantalum (Ta), and tantalum nitride (TaN). Examples of materials for the conductive film include tungsten (W) and aluminum (Al). The barrier film is not an essential component. The number of the first contact CT1 is not particularly limited and is appropriately adjusted in accordance with a desired current amount.

The second contact CT2 is formed in the insulating layer IL such that the second contact CT2 reaches the second conductive film CF2 without overlapping with the second semiconductor region SR2 in plan view. The second contact CT2 is formed at a position that differs from the second semiconductor region SR2 in plan view. The second contact CT2 is located outside the region surrounded by the buried insulating film BIF in plan view. The second contact CT2 may indirectly contact with the semiconductor substrate SUB through the second conductive film CF2, or may directly contact with the semiconductor substrate SUB. The second contact CT2 is preferably formed such that the second contact CT2 reaches the second conductive film CF2. As a result, a height of the first contact CT1 becomes approximately the same as a height of the second contact CT2. As a result, when the through hole for the first contact CT1 is formed in the insulating layer IL, it is possible to suppress a depth of the first recess portion RP1 on the first conductive film CF1 is too large by overetching. This makes the semiconductor device SDs more reliable. An exemplary configuration of the second contact CT2 is the same as that of the first contact CT1. The number of the second contacts CT2 is not particularly limited, and may be appropriately adjusted in accordance with a desired amount of current.

(Method of Manufacturing Semiconductor Device)

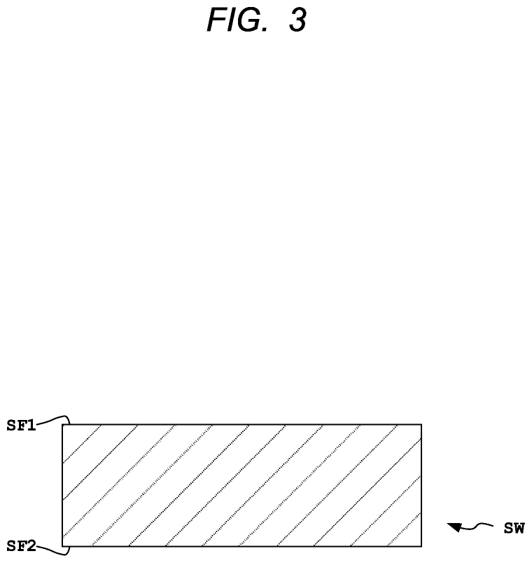

Next, an exemplary method of manufacturing the semiconductor device SD according to the present embodiment will be described. FIGS. 3 to 8 are a cross sectional views showing exemplary step included in the method of manufacturing the semiconductor device SD.

The method of manufacturing the semiconductor device SD according to the embodiment includes (1) providing a semiconductor wafer SW, (2) forming the buried insulating film BIF, (3) forming the first semiconductor region SR1, the second semiconductor region SR2, and the third semiconductor region SR3, (4) forming the first conductive film CF1 and the second conductive film CF2, (5) forming the insulating layer IL, and (6) forming the first contact CT1 and the second contact CT2.

(1) Providing of a Semiconductor Wafer SW

First, as shown in FIG. 3, a semiconductor wafer SW is provided. The semiconductor wafer SW includes the first surface SF1 and the second surface SF2 opposite to each other. The semiconductor wafer SW may be manufactured or purchased as a commercial product. The semiconductor wafer SW is, for example, a silicon wafer.

(2) Forming the Buried Insulating Film BIF

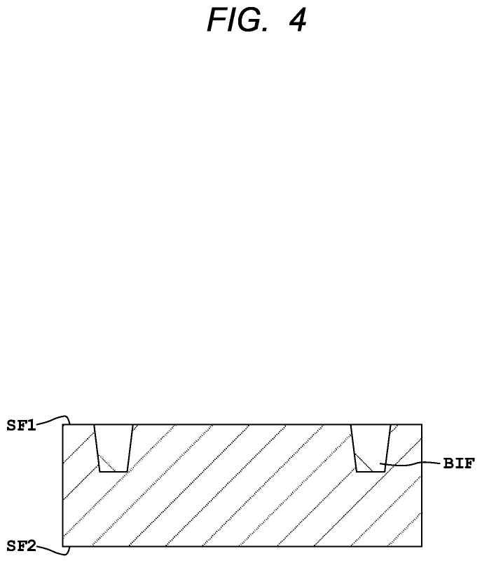

Subsequently, the buried insulating film BIF is then formed on the semiconductor wafer SW as shown in FIG. 4. After forming a recess on the first surface SF1 of the semiconductor wafer SW by etching method, then the buried insulating film BIF may be formed by filling the recess with an insulating film. The buried insulating film BIF may be formed by oxidizing a portion of the first surface SF1 of the semiconductor wafer SW by LOCOS method.

(3) Forming the First Semiconductor Region SR1, the Second Semiconductor Region SR2 and the Third Semiconductor Region SR3

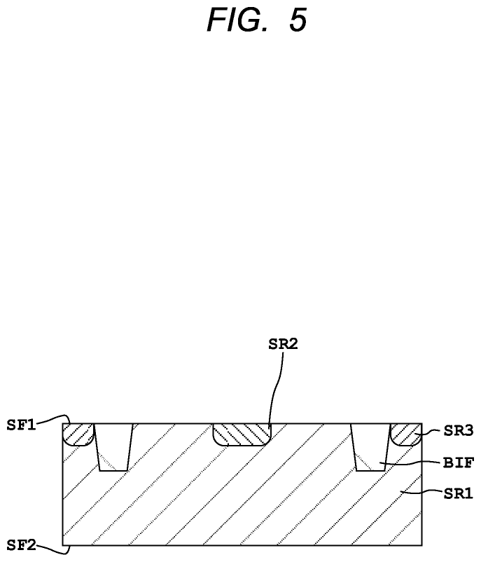

Subsequently, as shown in FIG. 5, the first semiconductor region SR1, the second semiconductor region SR2 and the third semiconductor region SR3 are formed in a desired region of the semiconductor wafer SW. The first semiconductor region SR1, the second semiconductor region SR2, and the third semiconductor region SR3 are formed by, for example, ion implantation method and activation annealing. Although not particularly shown, in the ion implantation method, a resist mask is formed on a region other than a region where ion implantation is to be performed.

(4) Forming the First Conductive Film CF1 and the Second Conductive Film CF2

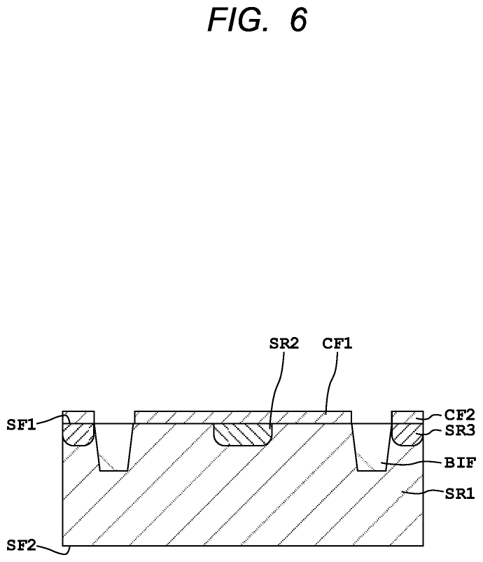

Subsequently, the first conductive film CF1 and the second conductive film CF2 are formed on the first surface SF1 of the semiconductor substrate SUB, as shown in FIG. 6. A Method of forming the first conductive film CF1 and the second conductive film CF2 is not particularly limited. For example, after the semiconductor layer is formed on the first surface SF1 of the semiconductor substrate SUB by a sputtering method, the semiconductor layer is patterned into a desired shape. Subsequently, a metal layer is formed on the semiconductor layer by, for example, a sputtering method, and annealing treatment is performed to form a silicide layer on the semiconductor layer. Thus, the first conductive film CF1 and the second conductive film CF2 is formed. The material of the semiconductor layer is, for example, silicon. The material of the metal layer is, for example, cobalt or nickel.

(5) Forming the Insulating Layer ILs

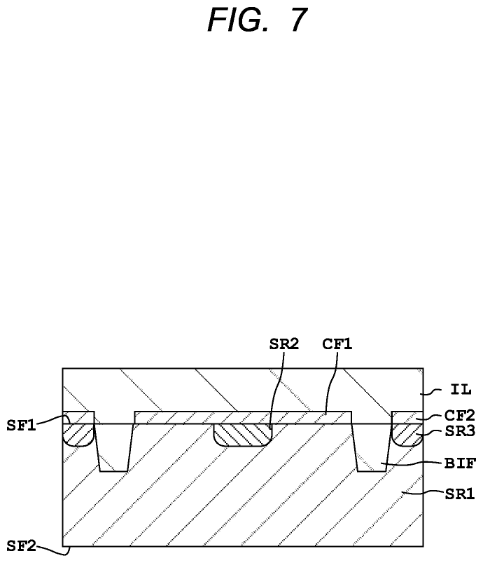

Subsequently, as shown in FIG. 7, the insulating layer IL is formed on the first surface SF1 of the semiconductor substrate SUB so as to cover the first conductive film CF1 and the second conductive film CF2. The method of forming the insulating layer IL is, for example, a CVD method.

(6) Forming the First Contact CT1 and the Second Contact CT2

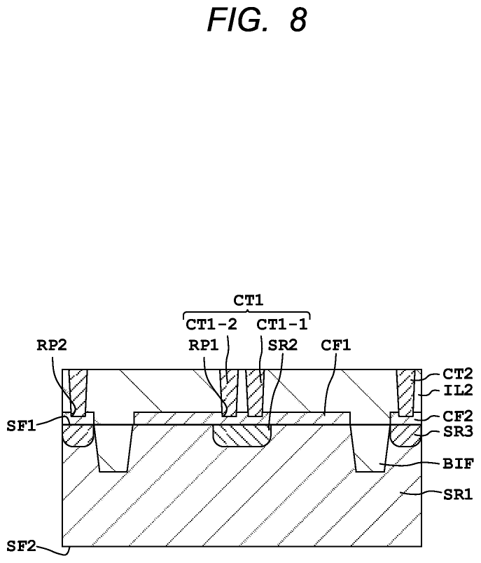

Subsequently, as shown in FIG. 8, the plurality of first contacts CT1 and the plurality of second contacts CT2 are formed in the insulating layer IL. After forming the through hole in insulating layer IL, the first contact CT1 and the second contact CT2 are respectively formed by filling the through hole with a conductive material. The through hole for the first contact CT1 is formed in the insulating layer IL so as to reach the first conductive film CF1. The through hole for the second contact CT2 is formed in the insulating layer IL so as to reach the second conductive film CF2. At this instance, it is preferable that a depth of the through hole for the first contact CT1 and a depth of the through hole for the second contact CT2 are equal to each other. Thus, it is possible to suppress that the first recess portion RP1 formed on the first conductive film CF1, and the second recess portion RP2 formed on the second conductive film CF2 are unintentionally deepened by overetching.

Subsequently, although not particularly shown, a wiring layer is formed on the insulating layer IL. Finally, by dicing the structures obtained by the above steps, a plurality of semiconductor devices SD singulated are obtained.

The semiconductor device SD according to the present embodiment is manufactured by the above manufacturing method.

(Effect of the Second Semiconductor Region SR2)

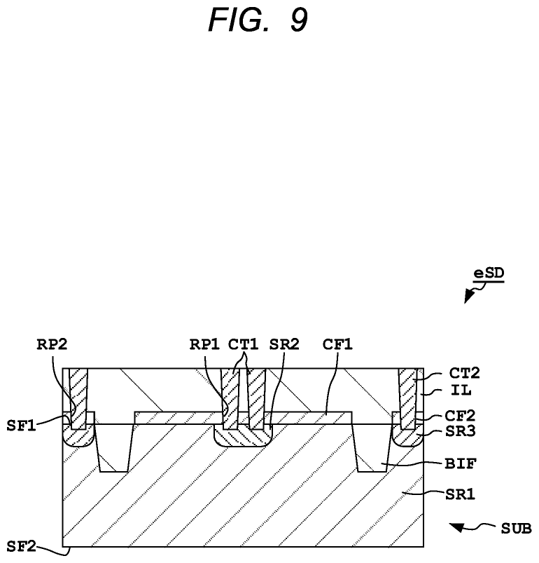

Here, the operation of the second semiconductor region SR2 is described. FIG. 9 is a cross sectional view showing an exemplary configuration of a main portion of a semiconductor device eSD according to examined example.

As described above, (6) in the step of forming the first contact CT1 and the second contact CT2, the through hole is formed in the insulating layer I L. At this instance, if the insulating layer IL remains between the first contact CT1 and the first conductive film CF1, and between second contact CT2 and second conductive film CF2, the resistivity is increased. Generally, when forming the through hole, in order to remove the insulating layer IL as much as possible, overetching is performed. Therefore, the through hole, not only the insulating layer IL, it may also penetrate the first conductive film CF1 and the second conductive film CF2. As a consequence, as shown in FIG. 9, the first contact CT1 reaching the second semiconductor region SR2 of the semiconductor substrate SUB may be formed. At this instance, if the second semiconductor region SR2 is not formed in the semiconductor substrate SUB, the first contact CT1 contacts with both the first conductive film CF1 and the first semiconductor region SR1 constituting the Schottky barrier diagram. As a result, the Schottky barrier diode will not operate properly.

In contrast, in the present embodiment, the first contact CT1, in plan view, overlaps with the second semiconductor region SR2. Therefore, as shown in FIG. 9, even if the first contact CT1 penetrates the first conductive film CF1, it is possible to suppress the first contact CT1 reaches the first semiconductor region SR1 by the second semiconductor region SR2. When a lower end portion of the first contact CT1 is formed in the second semiconductor region SR2, a function as a Schottky barrier diode is not lost. Therefore, the reliability of the semiconductor device SD can be improved by the second semiconductor region SR2.

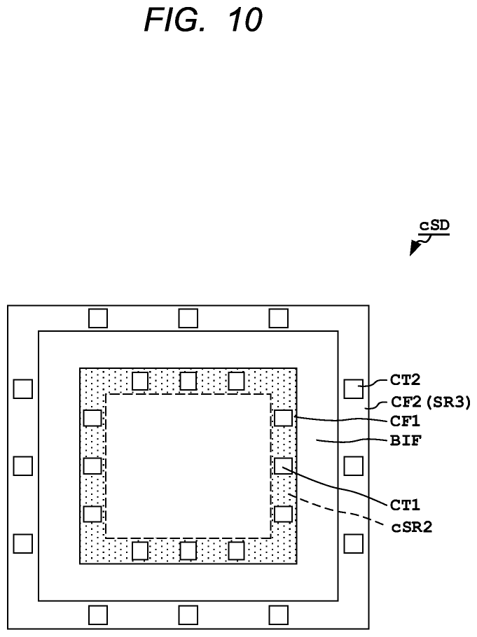

The effect of the second semiconductor region SR2, based on a size of the semiconductor region is described. FIG. 10 is a plan view showing an exemplary configuration of a main portion of a semiconductor device cSD according to the comparative example.

As shown in FIG. 10, in the semiconductor device cSD according to the comparative example, an entire outer edge of a second semiconductor region cSR2 is adjacent to the buried insulating film BIF. Therefore, depending on the number and size and arrangement of the first contact CT1, in plan view, the ratio of the second semiconductor region cSR2 at a contact surface of the semiconductor substrate SUB and the first conductive film CF1 is increased. This means that a region that does not operate as a Schottky barrier diode becomes larger. Consequently, from the viewpoint of providing a region that operates as a Schottky barrier diode, the semiconductor device cSDs become larger and consequently more costly.

In contrast, in the present embodiment, as shown in FIG. 1, in the direction along the first side S1, the distance D between the second semiconductor region SR2 and the buried insulating film BIF is greater than the distance d between the first contact CT1-1 and the first contact CT1-2. Also in the direction along the second side S2, the distance D is greater than the distance d. Therefore, in the present embodiment, it is possible to reduce the occupied area of the second semiconductor region SR2 at a contact surface of the semiconductor substrate SUB and the first conductive film CF1. According to a simulation conducted by the present inventors, when supplying the same current value to the Schottky barrier diode, in the present embodiment, a size of the second semiconductor region SR2 can be reduced by 17% compared to the semiconductor device cSD according to the comparative example. That is, compared with the semiconductor device cSD according to the comparative examples, the semiconductor device SD according to the present embodiment can obtain equivalent characteristics even in a smaller area. Consequently, the semiconductor device SDs can be made more compact and less costly.

(Effect)

In the semiconductor device SD according to the present embodiment, the first contact CT1 is formed such that the first contact CT1 overlaps with the second semiconductor region SR2 in plan view. As a result, even if the first contact CT1 reaches the second semiconductor region SR2 of the semiconductor substrate SUB, the Schottky barrier diode can operate properly if the first contact CT1 does not reach the first semiconductor region SR1. Thus, according to the present embodiment, it is possible to increase the reliability of the semiconductor device SD.

Furthermore, in the present embodiment, in the direction along the first side S1 of the second semiconductor region SR2, the distance D between the second semiconductor region SR2 and the buried insulating film BIF is greater than the distance d between the first contact CT1-1 and the first contact CT1-2. Therefore, the ratio of the region that does not operate as a Schottky barrier diode is reduced (the second semiconductor region SR2), and the ratio of the region that operates as a Schottky barrier diode (the first semiconductor region SR1) is increased. As a consequence, the characteristics of the semiconductor device SD can also be improved.

### First Modification

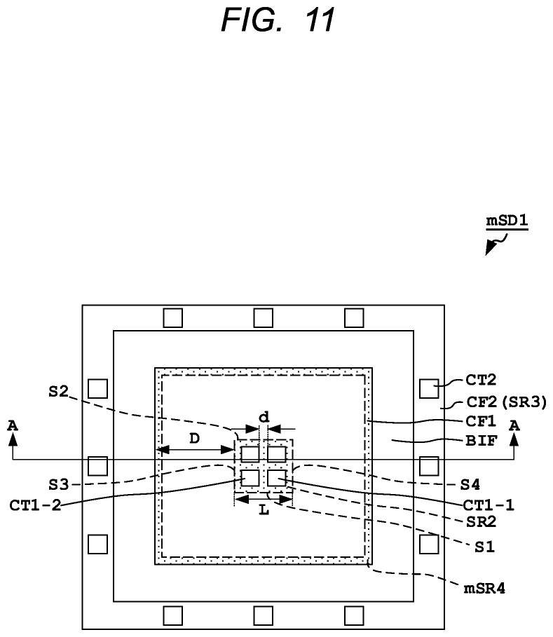

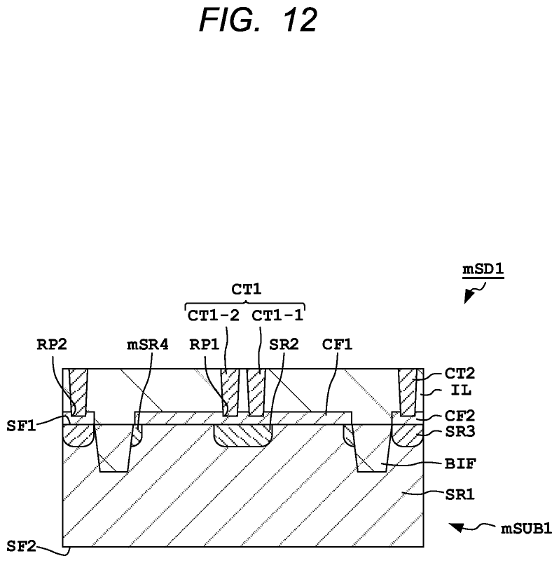

FIG. 11 is a plan view showing an exemplary configuration of a main portion of a semiconductor device mSD1 according to first modification of the present embodiment. FIG. 12 is a cross-sectional view showing an exemplary configuration of the main portion of the semiconductor device mSD1 according to the first modification of the present embodiment. FIG. 12 is a cross-sectional view taken along line A-A of FIG. 11.

The semiconductor substrate mSUB1 of the semiconductor device mSD1 according to first modification further includes a fourth semiconductor region mSR4. The fourth semiconductor region mSR4, in plan view, is formed without overlapping with any contact formed in the insulating layer IL. The fourth semiconductor region mSR4, in plan view, is formed such that the fourth semiconductor region mSR4 is adjacent to the buried insulating film BIF between the buried insulating film BIF and the second semiconductor region SR2. A planar shape of the fourth semiconductor region mSR4 is an annular shape. The fourth semiconductor region mSR4 has the same second conductivity type as the second semiconductor region SR2. The surface of the fourth semiconductor region SR4 is located on the first surface SF1 of the semiconductor substrate SUB. Examples of impurity concentration of the fourth semiconductor region SR4 are the same as those of the second semiconductor region SR2.

The semiconductor device mSD1 according to first modification includes a fourth semiconductor region mSR4 adjacent to an inner edge of the buried insulating film BIF. Thus, a leakage current flowing through the inner edge of the buried insulating film BIF is reduced. Consequently, the characteristics of the semiconductor device mSD1 can be further improved.

### Second Modification

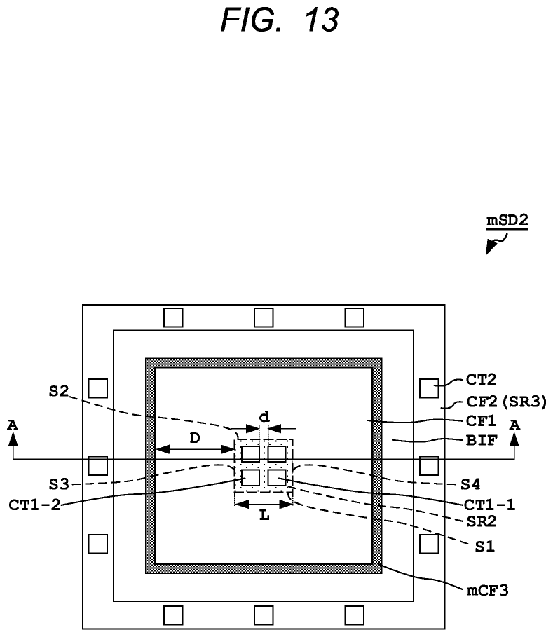

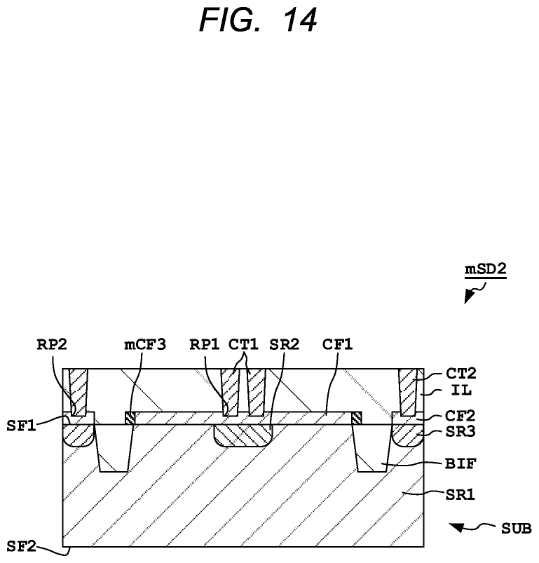

FIG. 13 is a plan view showing an exemplary configuration of a main portion of a semiconductor device mSD2 according to a second modification of the present embodiment. FIG. 14 is a cross-sectional view showing an exemplary configuration of the main portion of the semiconductor device mSD2 according to the second modification of the present embodiment. FIG. 14 is a cross-sectional view taken along line A-A of FIG. 13.

The semiconductor device mSD2 according to the second modification includes a third conductive film mCF3. The third conductive film mCF3 is formed such that the third conductive film mCF3 overlaps with the inner edge of the buried insulating film BIF in plan view. A planar shape of the third conductive film mCF3 is an annular shape. The third conductive film mCF3 is electrically conductive. The material of the semiconductive film mCF3 is polycrystalline silicon.

The semiconductor device mSD2 according to the second modification includes a third conductive film mSF3 located on the inner edge of the buried insulating film BIF. Thus, a leakage current flowing through the inner edge of the buried insulating film BIF is reduced. Consequently, the characteristics of the semiconductor device mSD2 can be further improved.

### Third Modification

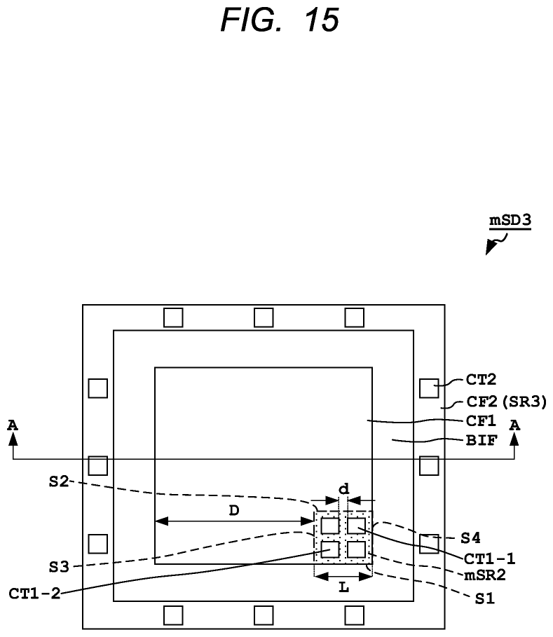

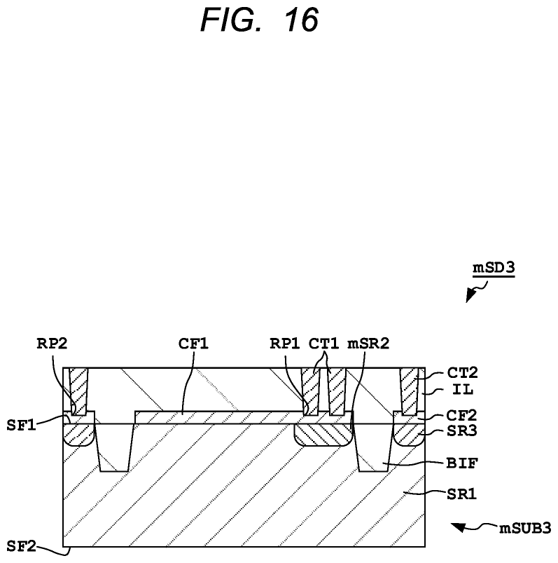

FIG. 15 is a plan view showing an exemplary configuration of a main portion of a semiconductor device mSD3 according to third modification of the present embodiment. FIG. 16 is a cross-sectional view showing an exemplary configuration of a main portion of a semiconductor device mSD3 according to the third modification of the present embodiment. FIG. 16 is a cross-sectional view taken along line A-A of FIG. 15.

The semiconductor device mSD3 according to third modification differs from the semiconductor device SD according to the embodiment in that the position of the second semiconductor region mSR2 formed in the semiconductor substrate mSUB3. The second semiconductor region mSR2 is formed such that the second semiconductor region mSR2 is located at a corner of a region surrounded by the buried insulating film BIF in plan view. In other words, the first side S1 and the fourth side S4 of the second semiconductor region mSR2, in plan view, contacts with the inner edge of the buried insulating film BIF. Thus, as the same manner as first modification, the leakage current is reduced in the portion that is adjacent to the second semiconductor region mSR2, of the buried insulating film BIF. As a consequence, the characteristics of the semiconductor device mSD4 can be further improved.

It should be noted that the present invention is not limited to the above embodiments, and various modifications can be made without departing from the gist thereof. In the above embodiment, a case where the first contact CT1 does not penetrate the first conductive film CF1 is described. However, the first contact CT1 may reach the second semiconductor region SR2 without contacting the first semiconductor region SR1 (see FIG. 9).

In the above embodiment, in the direction along the first side S1 of the second semiconductor region SR2, the distance D between the third side S3 of the second semiconductor region SR2 and the buried insulating film BIF is greater than the distance d between the first contact CT1-1 and the first contact CT1-2. However, the distance D between at least one of the first side S1, the second side S2, the third side S3, and the fourth side S4 of the second semiconductor region SR2, and the buried insulating film BIF may be greater than the distance d between the first contact CT1-1 and the first contact CT1-2. From the viewpoint of further enhancing the effects of the present invention, it is preferable that the distance D between each of the first side S1, the second side S2, the third side S3, and the fourth side S4 of second semiconductor region SR2, and the buried insulating film BIF is greater than the distance d between the first contact CT1-1 and the first contact CT1-2.

In addition, even when a specific numerical value example is described, it may be a numerical value exceeding the specific numerical value, or may be a numerical value less than the specific numerical value, except when it is theoretically obviously limited to the numerical value. In addition, the component means “B containing A as a main component” or the like, and the mode containing other components is not excluded.

What is claimed is:

1. A semiconductor device comprising:
a first semiconductor region of a first conductivity type formed on a semiconductor substrate;
a second semiconductor region of a second conductivity type opposite to the first conductivity type, formed on the first semiconductor region and arranged on an upper surface of the semiconductor substrate;
a buried insulating film formed on the first semiconductor region such that the buried insulating film surrounds the second semiconductor region in plan view;
a first conductive film formed on the first semiconductor region and the second semiconductor region such that the first conductive film directly contacts with both of the first semiconductor region and the second semiconductor region;
an insulating layer formed on the first conductive film; and
a plurality of first contacts and a plurality of second contacts formed on the second semiconductor region such that the plurality of first contacts and the plurality of second contacts penetrates the insulating layer and reaches the first conductive film;
wherein, the plurality of first contacts is along one side of the second semiconductor region in plan view and
wherein, the plurality of second contacts is adjacent to the plurality of first contacts in plan view.

2. The semiconductor device according to claim 1,
wherein, the first conductive film includes a silicide layer.

3. The semiconductor device according to claim 2,
wherein, the silicide layer is cobalt silicide layer or a nickel silicide layer.

4. The semiconductor device according to claim 1,
wherein, the second semiconductor region is spaced apart from the buried insulating film in plan view.

5. The semiconductor device according to claim 1,
wherein, the second semiconductor region is adjacent to the buried insulating film in plan view.

6. The semiconductor device according to claim 5,
wherein, one side of the second semiconductor region contacts with the buried insulating film in plan view.

7. The semiconductor device according to claim 1, further comprising:
a third semiconductor region of the first conductivity formed on the first semiconductor region, arranged on the upper surface of the semiconductor substrate and outside of the buried insulating film in plan view;
a second conductive film formed on the third semiconductor region such that the second conductive film directly contacts with the third semiconductor region; and
a plurality of third contacts formed on the third semiconductor region such that the plurality of third contacts penetrates the insulating layer and reaches the second conductive film.

8. The semiconductor device according to claim 4, further comprising:
a fourth semiconductor region of the second conductivity type formed between the buried insulating film and the second semiconductor region in plan view such that the third semiconductor region is adjacent to the buried insulating film.

9. The semiconductor device according to claim 8,
wherein, the fourth semiconductor region is formed without overlapping with any the plurality of first contacts or the plurality of second contacts in plan view.

10. The semiconductor device according to claim 5, further comprising:
a fourth semiconductor region of the second conductivity type formed between the buried insulating film and the second semiconductor region in plan view such that the third semiconductor region is adjacent to the buried insulating film.

11. The semiconductor device according to claim 10,
wherein, the fourth semiconductor region is formed without overlapping with any the plurality of first contacts or the plurality of second contacts in plan view.

12. The semiconductor device according to claim 4, further comprising:
a third conductive film formed such that the third conductive film overlaps with an inner edge portion of the buried insulating film in plan view.

13. The semiconductor device according to claim 5, further comprising:
a third conductive film formed such that the third conductive film overlaps with an inner edge portion of the buried insulating film in plan view.

14. The semiconductor device according to claim 1,
wherein, a Schottky barrier diode is formed by the first conductive film and the first semiconductor region.

15. The semiconductor device according to claim 14,
wherein, a Schottky barrier diode is not formed by the first conductive film and the second semiconductor region.
